(19) United States
(12) Patent Application Publication
(10) Pub. No.: US 2026/0133257 A1
(43) Pub. Date: May 14, 2026

(54) VEHICLE AND METHOD FOR ESTIMATING DEGRADATION OF BATTERY

(71) Applicant: TOYOTA JIDOSHA KABUSHIKI KAISHA, Toyota-shi (JP)

(72) Inventor: Kumiko NODA, Nagoya-shi (JP)

(73) Assignee: TOYOTA JIDOSHA KABUSHIKI KAISHA, Toyota-shi (JP)

(21) Appl. No.: 19/291,996

(22) Filed: Aug. 6, 2025

(30) Foreign Application Priority Data
Nov. 11, 2024 (JP) 2024-196535

(51) Int. Cl. G01R 31/392; G01R 31/367; G01R 31/374; G01R 31/3828

(52) U.S. Cl. CPC G01R 31/392; G01R 31/367; G01R 31/374; G01R 31/3828

(57) ABSTRACT

A vehicle includes: a traction motor-generator; a PCU that drives the motor-generator; a main battery that is charged and discharged by the PCU while the vehicle is in use; and a processor. When the vehicle is in use, the processor calculates a cycle degradation amount of the main battery by executing a cycle degradation process using the amount of electric charge that has flowed through the main battery. When the vehicle is not in use, the processor calculates a calendar degradation amount of the main battery by executing a calendar degradation process using the period of inactivity of the main battery. The processor estimates a degree of degradation of the main battery based on the sum of the cycle and calendar degradation amounts. Even when the vehicle is in use, the processor executes the calendar degradation process when the amount of electric charge is less than a reference value.

### CROSS-REFERENCE TO RELATED APPLICATION

This application claims priority to Japanese Patent Application No. 2024-196535 filed on Nov. 11, 2024. The disclosure of the above-identified application, including the specification, drawings, and claims, is incorporated by reference herein in its entirety.

### BACKGROUND

### 1. Technical Field

The present disclosure relates to vehicles and methods for estimating degradation of a battery.

### 2. Description of Related Art

Japanese Unexamined Patent Application Publication No. 2019-53074 (JP 2019-53074 A) discloses a degradation estimation device that can accurately estimate degradation of an energy storage element. The degradation estimation device includes an acquisition unit and an estimation unit. The acquisition unit acquires time-series data on the state of charge (SOC) of the energy storage element. The estimation unit calculates a cycle degradation value by using a coefficient based on the magnitude of variation in SOC in the time-series data acquired by the acquisition unit, and estimates degradation of the energy storage element based on the sum of the calculated cycle degradation value and a non-cycle degradation value. The cycle degradation value indicates degradation of the energy storage element caused by current flow, and the non-cycle degradation value indicates degradation of the energy storage element not caused by current flow.

### SUMMARY

There is a constant demand for accurately estimating the degree of degradation of a battery mounted on a vehicle. The inventors have focused on the fact that, when the degree of degradation of a battery is estimated by distinguishing between degradation caused by current flow and degradation not caused by current flow, the accuracy of estimating the degree of degradation tends to decrease under certain conditions.

The present disclosure has been made to address the above issue, and one object of the present disclosure is to improve the accuracy of estimating the degree of degradation of a battery mounted on a vehicle.

A vehicle according to a first aspect of the present disclosure includes: a traction motor-generator; a drive device configured to drive the motor-generator; a battery configured to be charged and discharged by the drive device while the vehicle is in use; and a processor. The processor is configured to, when the vehicle is in use, calculate a cycle degradation amount of the battery by executing a cycle degradation process using the amount of electric charge that has flowed through the battery, and when the vehicle is not in use, calculate a calendar degradation amount of the battery by executing a calendar degradation process using a period of inactivity of the battery, and estimate a degree of degradation of the battery based on the sum of the cycle degradation amount and the calendar degradation amount. The processor is configured to, even when the vehicle is in use, execute the calendar degradation process when the amount of electric charge is less than a reference value.

A method for estimating degradation of a battery according to a second aspect of the present disclosure is a method for estimating degradation of a battery mounted on a vehicle. The method includes estimating a degree of degradation of the battery by a processor. The estimating includes: when the vehicle is in use, calculating a cycle degradation amount of the battery by executing a cycle degradation process using the amount of electric charge that has flowed through the battery; when the vehicle is not in use, calculating a calendar degradation amount of the battery by executing a calendar degradation process using a period of inactivity of the battery; even when the vehicle is in use, executing the calendar degradation process when the amount of electric charge is less than a reference value; and estimating the degree of degradation based on the sum of the cycle degradation amount and the calendar degradation amount.

The present disclosure can improve the accuracy of estimating the degree of degradation of a battery mounted on a vehicle.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a block diagram showing an example of the overall configuration of a vehicle according to an embodiment;

FIG. 2 shows tables illustrating a cycle degradation coefficient and a calendar degradation coefficient;

FIG. 3 is a graph illustrating the reason why an error occurs in a cycle degradation amount;

FIG. 4 is a flowchart showing an example of the processing procedure of a degradation estimation process according to the embodiment;

FIG. 5 shows graphs illustrating simulated travel patterns for determining the cycle degradation coefficient; and

FIG. 6 shows graphs illustrating the cycle degradation coefficient and the calendar degradation coefficient.

### DETAILED DESCRIPTION OF EMBODIMENTS

An embodiment of the present disclosure will be described in detail below with reference to the drawings. The same or corresponding portions are denoted by the same signs throughout the drawings, and description thereof will not be repeated.

### Embodiment

### Vehicle Configuration

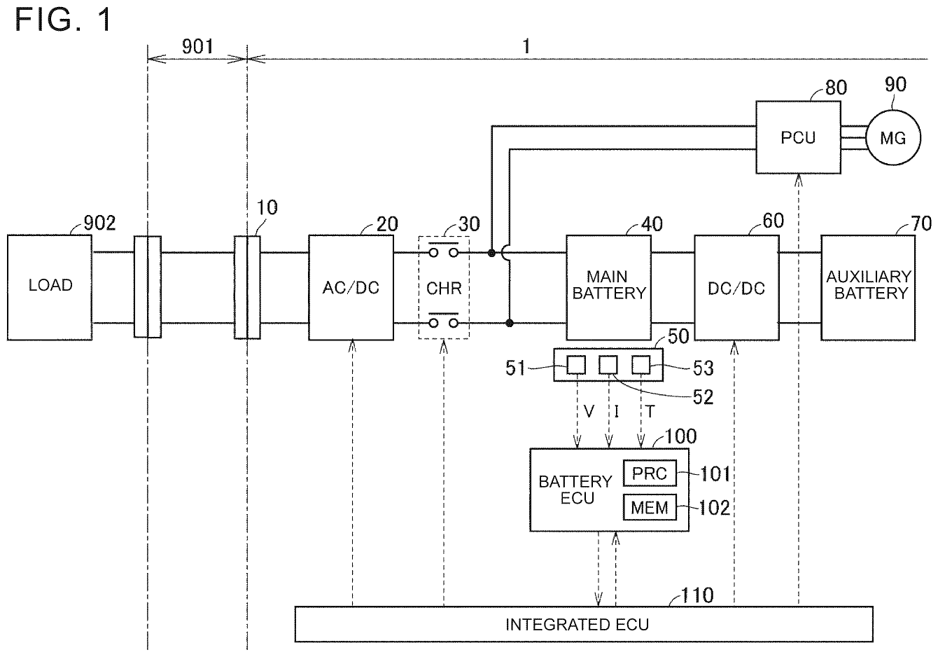

FIG. 1 is a block diagram showing an example of the overall configuration of a vehicle according to the present embodiment. In this example, a vehicle 1 is a battery electric vehicle. However, the type of vehicle 1 is not limited to this as long as it is a vehicle equipped with a traction battery. The vehicle 1 may be a hybrid electric vehicle, a plug-in hybrid electric vehicle, or a fuel cell electric vehicle.

The vehicle 1 includes an inlet 10, an alternating current to direct current (AC-DC) converter 20, a charging relay 30, a main battery 40, a monitoring unit 50, a direct current to direct current (DC-DC) converter 60, an auxiliary battery 70, a power control unit (PCU) 80, a motor-generator 90, a battery electronic control unit (ECU) 100, and an integrated ECU 110.

The inlet 10 is configured to allow a charging connector provided at a distal end of a charging cable 901 to be inserted therein. The vehicle 1 is configured to be charged with electric power supplied from an external power source (not shown) installed outside the vehicle 1 via the charging cable 901. This charging is herein referred to as “external charging.” The vehicle 1 is also configured to supply electric power to an external load 902. This power supply is herein referred to as “external power supply.” The external load 902 is, for example, a house, but may be various types of electrical devices. The inlet 10 corresponds to the “power supply port” according to the present disclosure.

The AC-DC converter 20 converts alternating current power supplied from the external power source via the inlet 10 to direct current power, and charges the main battery 40 with the direct current power. The AC-DC converter 20 also converts direct current power supplied from the main battery 40 to alternating current power, and supplies the alternating current power to the external load 902 via the inlet 10. The AC-DC converter 20 corresponds to the “power supply device” according to the present disclosure.

The charging relay 30 is electrically connected to a power line that connects the AC-DC converter 20 and the main battery 40. The charging relay 30 is opened and closed in accordance with control commands from the integrated ECU 110.

The main battery 40 is a battery pack including a plurality of cells. Each cell is an energy storage cell (secondary cell) such as a lithium-ion cell or a nickel metal hydride cell. The main battery 40 stores electric power for driving the motor-generator 90, and supplies the electric power to the motor-generator 90 through the PCU 80. The main battery 40 corresponds to the “battery” according to the present disclosure.

The monitoring unit 50 includes a voltage sensor 51, a current sensor 52, and a temperature sensor 53. The voltage sensor 51 detects the voltage V of the main battery 40. The current sensor 52 detects the current I flowing through the main battery 40. The temperature sensor 53 detects the temperature T of the main battery 40. Each sensor outputs a signal indicating its detection result to the battery ECU 100.

The DC-DC converter 60 charges the auxiliary battery 70 with electric power supplied from the main battery 40 in accordance with a control command from the integrated ECU 110. The DC-DC converter 60 corresponds to the “charging device” according to the present disclosure.

The auxiliary battery 70 is charged by the DC-DC converter 60, and supplies electric power to auxiliary devices (not shown) as needed.

The PCU 80 drives the motor-generator 90 in accordance with a control command from the integrated ECU 110. The PCU 80 corresponds to the “drive device” according to the present disclosure.

The motor-generator 90 is a traction motor-generator that rotates a drive shaft using electric power supplied from the main battery 40.

The battery ECU 100 includes a processor 101 such as a central processing unit (CPU), and a memory 102 such as a read-only memory (ROM) and a random access memory (RAM). The battery ECU 100 manages the main battery 40 based on input signals from the sensors of the monitoring unit 50 and on maps and programs stored in the memory 102. A primary process that is executed by the battery ECU 100 in the present embodiment is a “degradation estimation process,” namely a process of estimating the degree of degradation of the main battery 40. The degree of degradation of the main battery 40 refers to the extent to which the capacity (full charge capacity) of the main battery 40 has decreased.

Like the battery ECU 100, the integrated ECU 110 includes a processor and a memory (neither of which are shown). The integrated ECU 110 controls the devices (AC-DC converter 20, charging relay 30, DC-DC converter 60, and PCU 80) such that the vehicle 1 reaches a desired state, based on input signals from sensors installed in the vehicle 1 and maps and programs stored in the memory.

### Degradation Estimation Process

The battery ECU 100 is configured to execute the following two logics in the degradation estimation process: a cycle degradation logic and a calendar degradation logic. The cycle degradation logic and the calendar degradation logic correspond to the “cycle degradation process” and the “calendar degradation process” according to the present disclosure, respectively.

The cycle degradation logic is basically a process of calculating the amount of degradation (hereinafter referred to as “cycle degradation amount”) of the main battery 40 based on the amount of electric charge (unit: Ah) that has flowed through the main battery while the vehicle 1 is in use. The cycle degradation amount depends on the temperature of the main battery 40. The higher the temperature of the main battery 40, the greater the cycle degradation amount. Therefore, the battery ECU 100 calculates, for each temperature of the main battery 40 during a predetermined period, a minute degradation amount based on the amount of electric charge that has flowed through the main battery 40, and calculates a cycle degradation amount d1 by summing the calculated minute degradation amounts for all the temperatures.

More specifically, in the cycle degradation logic, the battery ECU 100 calculates the cycle degradation amount d1 according to the following Equation (1). In Equation (1), aⱼ represents a cycle degradation coefficient indicating a cycle degradation rate (cycle degradation amount per unit time), the amount of electric charge (current×time) is expressed in Ah, and j represents a natural number (j=1, 2, . . . , J) for distinguishing the temperatures of the main battery 40.

$$d 1 = {{\sum }^{J}}_{j = 1} {a}_{j} \times \sqrt{Ah} \qquad ( 1 )$$

The calendar degradation logic is a process of calculating the amount of degradation (hereinafter referred to as “calendar degradation amount”) of the main battery based on the period of inactivity of the main battery 40 while the vehicle 1 is not in use (while the vehicle 1 is powered off). The calendar degradation amount depends on the temperature and SOC of the main battery 40. The higher the temperature of the main battery 40, the greater the calendar degradation amount. The higher the SOC of the main battery 40, the greater the calendar degradation amount. Therefore, the battery ECU 100 calculates, for each combination (temperature, SOC) of the temperature and SOC of the main battery 40, a minute degradation amount based on the period of inactivity of the main battery 40, and calculates a calendar degradation amount d2 by summing the calculated minute degradation amounts for all the combinations (temperatures, SOCs).

More specifically, in the calendar degradation logic, the battery ECU 100 calculates the calendar degradation amount d2 according to the following Equation (2). In Equation (2), bⱼₖ represents a calendar degradation coefficient indicating a calendar degradation rate (calendar degradation amount per unit time), t represents the period of inactivity (e.g., the number of days), j represents a natural number (j=1, 2, . . . , J) for distinguishing the temperatures of the main battery 40, and k represents a natural number (k=1, 2, . . . , K) for distinguishing the SOCs of the main battery 40.

$$d 2 = {{\sum }^{J}}_{j = 1} {{\sum }^{K}}_{k = 1} {b}_{jk} \times \sqrt{t} \qquad ( 2 )$$

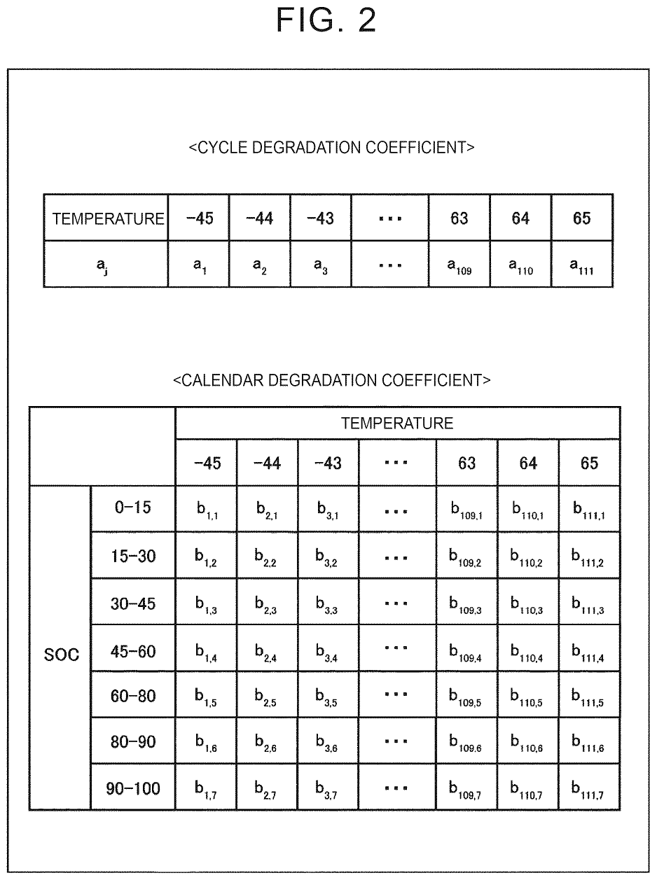

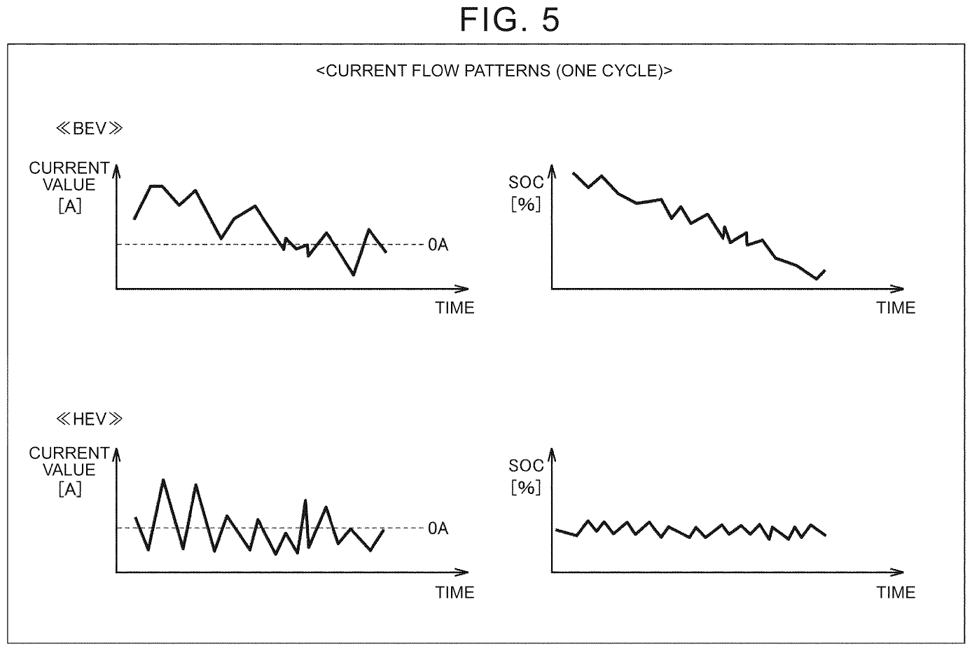

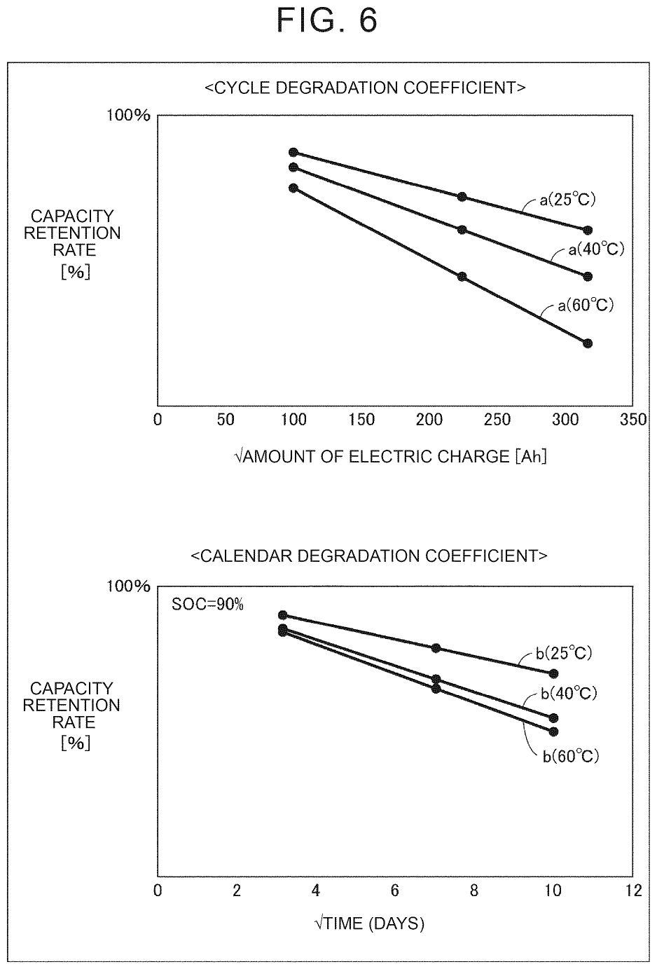

FIG. 2 shows tables illustrating the cycle degradation coefficient aⱼ and the calendar degradation coefficient bⱼₖ. In this example, based on prior experimental results, the cycle degradation coefficient aⱼ is determined for each 1° C. increment within the temperature range of the main battery 40 from −45° C. to 65° C. The summation is taken up to J=111. Similarly, based on prior experimental results, the calendar degradation coefficient bⱼₖ is determined for each 1° C. increment within the temperature range from −45° C. to 65° C. and for each 10% to 20% SOC increment within the SOC range from 0% to 100%. The summation is taken up to J=111 and K=7. The method for determining the cycle degradation coefficient aⱼ and the calendar degradation coefficient bⱼₖ will be described in detail later with reference to FIGS. 5 and 6.

The relationship between the temperature of the main battery 40 and the cycle degradation coefficient aⱼ as shown in FIG. 2 is stored in the memory 102 of the battery ECU 100 as, for example, a table (or may be stored therein as a map or a relational expression). Similarly, the relationship between the temperature and SOC of the main battery and the calendar degradation coefficient bⱼₖ is stored as, for example, a table in the memory 102 of the battery ECU 100. By referring to these tables, the battery ECU 100 can calculate the cycle degradation coefficient aⱼ from the temperature of the main battery 40, and can also calculate the calendar degradation coefficient bⱼₖ from the temperature and SOC of the main battery 40.

The battery ECU 100 also calculates the cycle degradation amount d1 using the cycle degradation coefficient aⱼ, and calculates the calendar degradation amount d2 using the calendar degradation coefficient bⱼₖ. The battery ECU 100 then calculates a total degradation amount D, namely the overall amount of degradation of the main battery 40, based on the sum of the time-integrated value of the cycle degradation amount d1 (cumulative cycle degradation amount D1) from the past (starting point) to the present and the time-integrated value of the calendar degradation amount d2 (cumulative calendar degradation amount D2) from the past (starting point) to the present (see Equation (3) below).

$$D 1 + D 2 = D \qquad ( 3 )$$

### Error in Cycle Degradation Amount

The present inventors focused on the fact that, when the total degradation amount D is calculated as described above, an error tends to occur in the cycle degradation amount d1 under certain conditions, which in turn tends to reduce the accuracy of calculating the total degradation amount D.

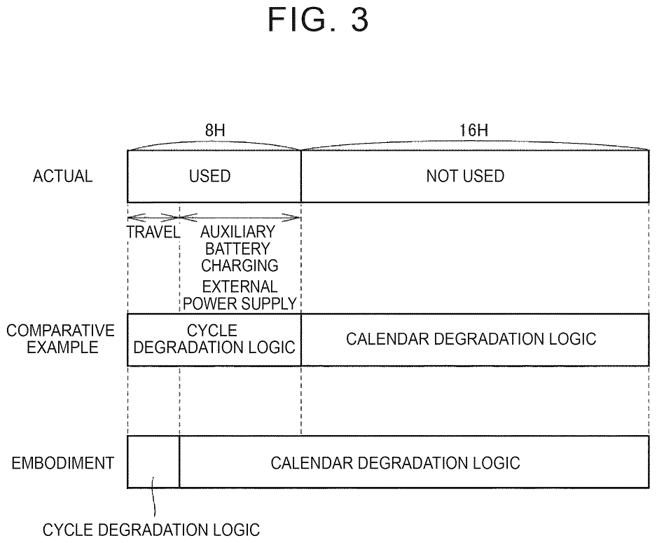

FIG. 3 is a graph illustrating the reason why an error occurs in the cycle degradation amount d1. It is herein assumed that, on a certain day (24 hours), the vehicle 1 is used for eight hours and is not used for 16 hours. In such a situation, as shown in a comparative example, it is possible to calculate the cycle degradation amount d1 in accordance with the cycle degradation logic for the eight hours during which the vehicle 1 is used, and to calculate the calendar degradation amount d2 in accordance with the calendar degradation logic for the 16 hours during which the vehicle 1 is not used.

The cycle degradation amount d1 (more specifically, the cycle degradation coefficient aⱼ for calculating the cycle degradation amount d1) is calculated on the assumption that the vehicle 1 travels (that is, on the assumption that the main battery 40 supplies electric power desired to implement a simulated travel pattern described below). However, as described above with reference to FIG. 1, the vehicle 1 has various functions in which the main battery 40 is used in a manner different from that when the vehicle 1 is traveling. More specifically, the electric power supplied from the main battery 40 may be used for charging the auxiliary battery 70 (hereinafter also referred to as “auxiliary battery charging”), or may be used for external power supply called vehicle-to-home (V2H) or vehicle-to-load (V2L).

The amount of electric charge (which may be the amount of electric charge per unit time, that is, the current value) that flows through the main battery 40 during auxiliary battery charging or external power supply is significantly smaller than the amount of electric charge that flows through the main battery 40 while the vehicle 1 is traveling. As an example, the current value while the vehicle 1 is traveling is 50 A, whereas the current value during auxiliary battery charging is 0.2 A, and the current value during external power supply is 5 A. That is, the current value while the vehicle 1 is traveling is one order of magnitude larger than the current value during external power supply, and is two orders of magnitude larger than the current value during auxiliary battery charging. Therefore, when the cycle degradation amount d1 is calculated on the assumption that the vehicle 1 travels throughout the entire eight-hour period, the cycle degradation amount d1 during auxiliary battery charging or external power supply is calculated as excessively large. As a result, an error may occur in the total degradation amount D.

Therefore, in the present embodiment, when the amount of electric charge that flows through the main battery 40 is less than a reference value (hereinafter also referred to as “during low-rate current flow”), the battery ECU 100 calculates the calendar degradation amount d2 in accordance with the calendar degradation logic (see the bottom of FIG. 3). That is, during low-rate current flow, the battery ECU 100 calculates the calendar degradation amount d2 in accordance with the calendar degradation logic instead of calculating the cycle degradation amount d1 in accordance with the cycle degradation logic, even when the vehicle 1 is in use. This reduces the occurrence of errors in the cycle degradation amount d1 during low-rate current flow. As a result, the accuracy of calculating the total degradation amount D can be improved.

### Process Flow

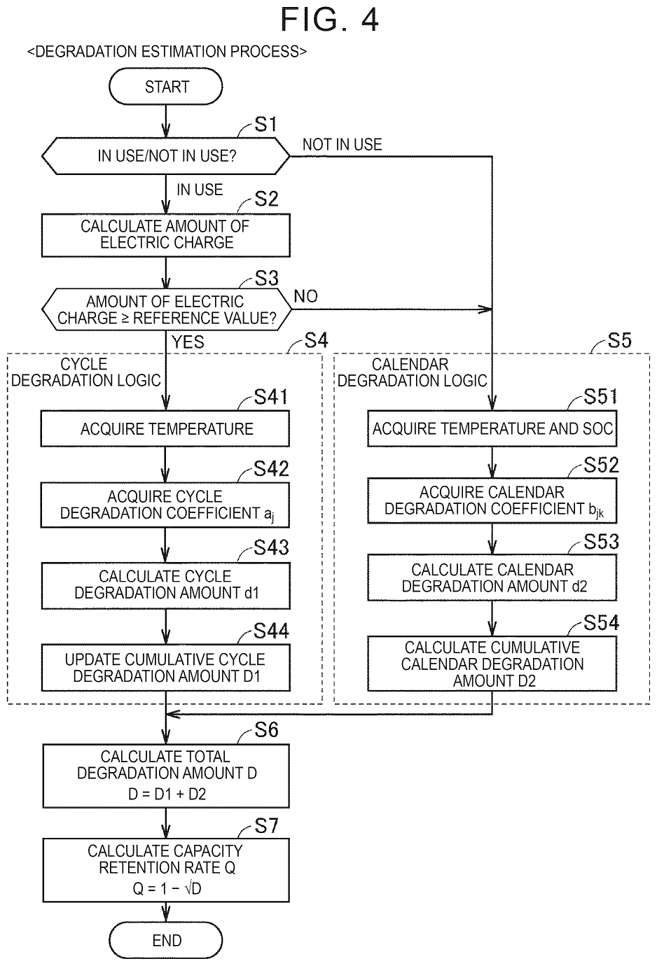

FIG. 4 is a flowchart showing an example of the processing procedure of the degradation estimation process according to the present embodiment. The process shown in this flowchart is executed when a predetermined condition is met (e.g., at predetermined control cycles). Each step is implemented by software processing performed by the battery ECU 100, but may alternatively be implemented by hardware (electrical circuits) arranged within the battery ECU 100. Hereinafter, the term “step” will be abbreviated as “S.”

In S1, the battery ECU 100 determines whether the vehicle 1 is in use or not in use. When the main battery 40 is in a state in which it can be energized (charged or discharged), the battery ECU 100 determines that the vehicle 1 is in use. The expression “the vehicle 1 is in use” includes when the vehicle 1 is traveling (which may include temporary stops etc.). However, this expression is not limited to this, and may also include during auxiliary battery charging, during external charging, during external power supply, etc. The battery ECU 100 may determine that the vehicle 1 is in use when the vehicle 1 is in the Ready-ON state.

On the other hand, when the main battery 40 is in a state in which it cannot be energized, the battery ECU 100 determines that the vehicle 1 is not in use. The expression “the vehicle 1 is not in use” typically refers to the state in which the main battery 40 is electrically isolated from other devices by, for example, opening a system main relay (SMR), not shown, provided in the main battery 40. The battery ECU 100 may determine that the vehicle 1 is not in use when the vehicle 1 is in the Ready-OFF state.

When the vehicle 1 is in use (“in use” in S1), the process proceeds to S2. On the other hand, when the vehicle 1 is not in use (“not in use” in S1), the process proceeds to S5.

In S2, the battery ECU 100 calculates the amount of electric charge during a predetermined period, based on the detection result of the current I acquired from the current sensor 52. In this example, the battery ECU 100 calculates the average current value (unit: A) during the predetermined period. However, the battery ECU 100 may alternatively calculate the integrated value of the current I over the predetermined period (unit: A·s, A·min, Ah, etc.) as the amount of electric charge.

In S3, the battery ECU 100 determines whether the average current value (alternatively, the integrated current value) calculated in S2 is greater than or equal to a reference value. The reference value is set to a current value (e.g., 5 A) that is small enough to be called low-rate current flow and that is sufficiently smaller than the average current value (e.g., 50 A) when the vehicle 1 is traveling. When the average current value is greater than or equal to the reference value (YES in S3), the process proceeds to S4, and the battery ECU 100 executes the cycle degradation logic. On the other hand, when the average current value is less than the reference value (NO in S3), the process proceeds to S5, and the battery ECU 100 executes the calendar degradation logic. Therefore, when the vehicle 1 is traveling (when the PCU 80 is in operation), the battery ECU 100 executes the cycle degradation logic because the amount of electric charge (the average current value) is greater than or equal to the reference value. During auxiliary battery charging or external power supply, the battery ECU 100 executes the calendar degradation logic because the amount of electric charge (the average current value) is less than the reference value.

In the cycle degradation logic of S4, the battery ECU 100 acquires the temperature of the main battery 40 (S41). The battery ECU 100 acquires the cycle degradation coefficient aⱼ according to the temperature of the main battery 40 by referring to the map stored in the memory 102 (S42). The battery ECU 100 calculates the cycle degradation amount d1 by multiplying the square root of the amount of electric charge Ah by the cycle degradation coefficient aⱼ according to the above Equation (1) (S43). As shown in Equation (4) below, the battery ECU 100 then calculates (updates) the current (nth) cumulative cycle degradation amount D1(n) by adding the newly calculated cycle degradation amount d1 to the previous ((n−1)th) cumulative cycle degradation amount D1(n−1) (S44). Thereafter, the process proceeds to S6.

$$D 1 ( n ) = D 1 ( n - 1 ) + d 1 \qquad ( 4 )$$

In the calendar degradation logic of S5, the battery ECU 100 acquires the temperature and SOC of the main battery 40 (S51). The battery ECU 100 acquires the calendar degradation coefficient bⱼₖ according to the temperature and SOC of the main battery 40 by referring to the map stored in the memory 102 (S52). The battery ECU 100 calculates the calendar degradation amount d2 by multiplying the square root of time t by the calendar degradation coefficient bⱼₖ according to the above Equation (2) (S53). As shown in Equation (5) below, the battery ECU 100 then calculates (updates) the current cumulative calendar degradation amount D2(n) by adding the newly calculated calendar degradation amount d2 to the previous cumulative calendar degradation amount D2(n−1) (S54). Thereafter, the process proceeds to S6.

$$D 2 ( n ) = D 2 ( n - 1 ) + d 2 \qquad ( 5 )$$

In S6, the battery ECU 100 calculates the sum of the cumulative cycle degradation amount D1 and the cumulative calendar degradation amount D2 as the total degradation amount D (see Equation (3) above).

In S7, the battery ECU 100 calculates the capacity retention rate Q (unit: %) from the total degradation amount D. Specifically, the battery ECU 100 calculates the capacity retention rate Q according to the following Equation (6).

$$Q = 100 - √ D \qquad ( 6 )$$

### Degradation Coefficient

FIG. 5 shows simulated travel patterns (i.e., current flow patterns of a battery identical to the main battery 40) for determining the cycle degradation coefficient. In this example, the upper part of this figure illustrates a simulated travel pattern for one cycle when the vehicle 1 is a battery electric vehicle (BEV). The lower part of this figure illustrates a simulated travel pattern for one cycle when the vehicle 1 is a hybrid electric vehicle (HEV). The horizontal axis represents time. The vertical axis of the left graphs represents the value of the current flowing through the battery, and the vertical axis of the right graphs represents the SOC of the battery. A current endurance test is conducted with the battery's ambient temperature kept constant. That is, the battery is charged and discharged so as to repeat a simulated travel pattern in which the current value and the SOC change as shown in the figure under a constant temperature. The capacity retention rate of the battery is measured after the test.

FIG. 6 shows graphs illustrating the cycle degradation coefficient a and the calendar degradation coefficient b. In general, the cycle degradation amount of a battery (the amount of decrease in capacity retention rate due to current flow) is proportional to the square root of the amount of electric charge that has flowed through the battery. Therefore, as shown in the figure, when the amount of electric charge that has flowed through the main battery 40 is plotted on the horizontal axis and the capacity retention rate of the main battery is plotted on the vertical axis, the relationship between the capacity retention rate and the square root of the amount of electric charge is represented by a straight line. The slope of this straight line corresponds to the cycle degradation coefficient a. In this example, the cycle degradation coefficient a (25° C.) at 25° C. is 0.0005, the cycle degradation coefficient a (40° C.) at 40° C. is 0.0007, and the cycle degradation coefficient a (60° C.) at 60° C. is 0.001.

In general, under conditions where the SOC is the same, the calendar degradation amount of a battery (the amount of decrease in capacity retention rate due to not being used) is proportional to the square root of the elapsed time. Therefore, as shown in the figure, when the square root of the elapsed time (elapsed days) is plotted on the horizontal axis and the capacity retention rate of the main battery 40 is plotted on the vertical axis, the relationship between the capacity retention rate and the square root of the elapsed time is also represented by a straight line. The slope of this straight line corresponds to the calendar degradation coefficient b. In this example, at SOC=90%, the calendar degradation coefficient b (25° C.) at 25° C. is 0.006, the calendar degradation coefficient b (40° C.) at 40° C. is 0.009, and the calendar degradation coefficient b (60° C.) at 60° C. is 0.01. Although not shown in the figure, similar straight lines are obtained under conditions where the temperature is the same but the SOC is different.

As described above, in the present embodiment, even when the vehicle 1 is in use, the battery ECU 100 executes the calendar degradation logic instead of the cycle degradation logic when the amount of electric charge that has flowed through the main battery 40 (the average current value or integrated current value over the predetermined period) is less than the reference value. The degradation pattern of the main battery 40 during low-rate current flow, namely during a period in which the amount of electric charge is less than the reference value, is closer to calendar degradation rather than to cycle degradation that is expected to occur when the vehicle 1 is traveling. Therefore, executing the calendar degradation logic can reduce the occurrence of errors in the cycle degradation amount d1 during low-rate current flow. According to the present embodiment, the accuracy of estimating the capacity retention rate Q of the main battery 40 mounted on the vehicle 1 can be improved.

The embodiment disclosed herein should be considered to be illustrative in all respects and not restrictive. The scope of the present disclosure is set forth in the claims rather than in the above description of the embodiment, and is intended to include all modifications within the meaning and scope equivalent to the claims.

What is claimed is:

1. A vehicle comprising:
a traction motor-generator;
a drive device configured to drive the motor-generator;
a battery configured to be charged and discharged by the drive device while the vehicle is traveling; and
a processor configured to, when the vehicle is in use, calculate a cycle degradation amount of the battery by executing a cycle degradation process using an amount of electric charge that has flowed through the battery, and when the vehicle is not in use, calculate a calendar degradation amount of the battery by executing a calendar degradation process using a period of inactivity of the battery, and estimate a degree of degradation of the battery based on a sum of the cycle degradation amount and the calendar degradation amount,
wherein the processor is configured to, even when the vehicle is in use, execute the calendar degradation process when the amount of electric charge is less than a reference value.

2. The vehicle according to claim 1, wherein the processor is configured to
in the cycle degradation process, calculate, for each temperature of the battery, an amount by multiplying a square root of the amount of electric charge by a cycle degradation rate of the battery, and calculate the cycle degradation amount by summing the calculated amounts for all of the temperatures, and
in the calendar degradation process, calculate, for each temperature of the battery and each state of charge of the battery, an amount by multiplying a square root of the period of inactivity by a calendar degradation rate of the battery, and calculate the calendar degradation amount by summing the calculated amounts for all of the temperatures and all of the states of charge.

3. The vehicle according to claim 2, wherein the processor is configured to calculate a current capacity retention rate of the battery as the degree of degradation by subtracting a square root of the sum from a capacity retention rate of the battery before degradation.

4. The vehicle according to claim 1, further comprising:
an auxiliary battery;
a charging device configured to charge the auxiliary battery with electric power supplied from the battery;
a power supply port; and
a power supply device configured to supply electric power to outside of the vehicle via the power supply port by using the electric power supplied from the battery,
wherein the processor is configured to, when the drive device is in operation, execute the cycle degradation process because the amount of electric charge is greater than or equal to the reference value, and when the charging device or the power supply device is in operation, execute the calendar degradation process because the amount of electric charge is less than the reference value.

5. A method for estimating degradation of a battery mounted on a vehicle, the method comprising estimating a degree of degradation of the battery by a processor, wherein the estimating includes
when the vehicle is in use, calculating a cycle degradation amount of the battery by executing a cycle degradation process using an amount of electric charge that has flowed through the battery,
when the vehicle is not in use, calculating a calendar degradation amount of the battery by executing a calendar degradation process using a period of inactivity of the battery,
even when the vehicle is in use, executing the calendar degradation process when the amount of electric charge is less than a reference value, and
estimating the degree of degradation based on a sum of the cycle degradation amount and the calendar degradation amount.
